(19) United States
(12) Patent Application Publication
(10) Pub. No.: US 2003/0141994 A1
(43) Pub. Date: Jul. 31, 2003

(54) Address encoding apparatus, address encoding method and address encoding program

(75) Inventors: Toshiyuki Ishioka, Osaka (JP); Tomohiko Kitamura, Osaka (JP); Hideyuki Kanzaki, Hyogo (JP)

Correspondence Address: McDERMOTT, WILL & EMERY, 600 13th Street, N.W., Washington, DC, 20005-3096, US

(73) Assignee: Matsushita Electric Industrial Co., Ltd.

(21) Appl. No.: 10/351,323

(22) Filed: Jan. 27, 2003

(30) Foreign Application Priority Data
Jan. 29, 2002 (JP) 2002-019689

(51) Int. Cl. H03M 7/00

(52) U.S. Cl. 341/50

(57) ABSTRACT

Even when an address, which is output from a processor to a memory via an address bus, is scrambled, the address that the processor accesses immediately after reset can be obtained by monitoring the bus, and so there was a possibility that a scrambling key used for scrambling could be deciphered relatively easily. In this invention, a non-encoded area is set in which addresses are not encoded, in an address space. An encoding unit encodes the input address based on the input address and set non-encoded area. For example, addresses that can be obtained easily by monitoring the bus are placed in this non-encoded area. By doing this, security is improved.

### BACKGROUND OF THE INVENTION

1. Field of the Invention

This invention relates to an address encoding apparatus, address encoding method and address encoding program that encodes an address that is output from a microprocessor for example to a device such as a memory device.

2. Description of the Related Art

In recent years it has become common to perform financial processing using consumer appliances such as STBs or mobile telephones. Together with this, the necessity of security protection of programs that are used for financial processing and the like has increased. In these kinds of appliances, a program is stored in a flash memory outside of the processor. In this case, the processor reads the program from the flash memory via a bus, and executes the program. In the case of transferring the program via the bus in this way, the bus is exposed from the chip, so there is a possibility that the program could be read by monitoring the bus. If this program is read, there is a danger that highly confidential information such as financial information used by the program could be leaked, or that the program could be illy used by using the read results. Therefore, a scrambling key is used to perform scrambling on the bus.

Generally, the address that the processor accesses immediately after being reset is fixed. This address can be found from specifications for the processor, etc.

Therefore, even though scrambling or some other form of encoding is performed for the bus, by monitoring an address that the processor accesses immediately after reset, it is possible to obtain the non-encoded address immediately after reset and the encoded address immediately after reset. In such a case, there is a high possibility that a scrambling key can be found from a relationship between an address without scrambling and the scrambled address. Therefore, even though encoding is performed for the bus, security cannot be sufficiently maintained.

### SUMMARY OF THE INVENTION

Taking these kinds of problems in the prior art into consideration, the object of the present invention is to provide an address encoding apparatus, address encoding method and address encoding program that make it difficult to obtain the address before encoding and the corresponding address after encoding, and that make it difficult to decipher an encoding key.

The present invention uses the following means in order to accomplish the objective described above.

In the address encoding apparatus of this invention, a non-encoded-area setting unit is used for setting a non-encoded area, in an internal address space, in which internal addresses are not encoded.

Also, a conversion unit outputs an external address, which is encoded internal address, based on an input internal address and the non-encoded area.

This conversion unit comprises an address-comparison unit and encoding unit.

The address-comparison unit determines whether an input internal address is contained in an encoded area that is an area in the internal address space other than the non-encoded area, or in the non-encoded area.

Also, the encoding unit encodes the input internal address to the external address in an area, in an external address space, corresponding to the encoded area only when it is determined that the input internal address is contained in the encoded area.

For example, there is an encoding-process unit and an output-selection unit in the encoding unit. When a scrambling process is used for encoding, the encoding-process unit performs scrambling bits of the input internal address except for upper specification bits. Also, when it is determined that the input internal address is contained in the encoded area, the output-selection unit selects the scrambled address from among the input internal address and scrambled address, and when it is determined that the input internal address is contained in the non-encoded area, the output-selection unit selects the input internal address.

When the external address that is selected by this output-selection unit is output via the address bus to a device such as a memory, by locating the address that the processor accesses immediately after reset in the non-encoded area, it is difficult to obtain the address before scrambling and the address after scrambling even though the address bus is observed. As a result, it becomes difficult to decipher the scrambling key that is used in scrambling and security of the program is improved.

The encoding-process unit can select part of lower bits of the specification bits based on the specification bits of the input internal address, and perform scrambling for not only bits of the input internal address except the specification bits, but also the selected bits. In this case, a unit area for scrambling becomes larger by the amount of the selected bits, and thus the analytical range for deciphering the scrambling key becomes larger. Therefore, security of the program is further improved.

On the other hand, it is also possible to construct the address encoding apparatus such that specification bits are not specified.

In this case, the encoding-process unit scrambles the input internal address.

Also, the non-encoded-area setting unit sets the non-encoded area, in the internal address space, in which addresses are not scrambled. The same area is set in an external address space as the non-encoded area, and the address-comparison unit determines whether the input internal address is contained in the encoded area that is an area in the internal address other than the non-encoded area, or in the non-encoded area, and also determines whether the scrambled address is contained in the encoded area that is an area in the external address other than the non-encoded area, or in the non-encoded area.

Also, when it is determined that the input internal address is contained in the encoded area and that the scrambled address is contained in the encoded area, the output-selection unit selects the scrambled address from among the input internal address and scrambled address. However, when it is determined that the input internal address is contained in the non-encoded area or that the scrambled address is contained in the non-encoded area, the output-selection unit selects the input internal address.

In this case as well, by locating the address that the processor accesses immediately after reset in the non-encoded area, it is difficult to obtain the address before scrambling and the address after scrambling even though the address bus is observed. If neither the address before encoding nor the address after encoding can be obtained, it is difficult to decipher the scrambling key that is used for the scrambling process. It is possible to make deciphering even more difficult by using a process other than the scrambling process for encoding.

In the case that a RAM page size differs from a size of a unit area for scrambling, there is a possibility that a scrambled address could be scattered over a plurality of pages, and that a performance of accessing the memory could drop. However, in that case, in order to keep the access performance from dropping, it is possible to use the encoding-process unit that scrambles part of bits of the input internal address. In that case, a page-size setting unit is prepared instead of the non-encoded-area setting unit. The page-size setting unit is used for setting the RAM page size. Also, according to a setting of the page-size setting unit, the encoding-process unit sets the number of non-scramble bits that are not scrambled, and scrambles bits of the input internal address except upper bits equal to the number of the non-scramble bits.

By doing this, scrambling is performed in units of page size, and it is possible to keep the performance of accessing the RAM from dropping due to scrambling.

In the case of there being a plurality of unit areas for scrambling, the encoding-process unit does not have to use the same scrambling key for scrambling, and that scrambling key can be different for each unit area for scrambling.

When the scrambling key is different for each unit area, even though the scrambling key for one unit area is deciphered, it is possible to avoid the program saved in the remaining unit areas from being improperly obtained. As a result, security of the program in the entire internal address space is improved.

Also, from another standpoint, this invention can provide an address encoding method comprising the processes described above.

Furthermore, from yet another standpoint, this invention can provide a program that executes the aforementioned address encoding method on a computer.

This program can be supplied to the market via telecommunication lines such as the Internet, or can be supplied to the market in the form of being recorded on a recording medium, such as a CD-ROM, that can be read by a computer.

This application is based on application No. 2002-019686 filed in Japan, the content of which is incorporated hereinto by reference.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic drawing showing the construction of the address encoding apparatus of a first embodiment of the invention.

FIG. 2 is a flowchart of the address encoding method of a first embodiment of the invention.

FIG. 3 is a drawing showing the arrangement of the non-encoded area and encoded area of the internal address space of a first embodiment of the invention.

FIG. 4 is a drawing showing the arrangement of the non-encoded area and encoded area of the external address space of a first embodiment of the invention.

FIG. 5 is a schematic drawing showing the construction of another form of the address encoding apparatus.

FIG. 6 is a flowchart of another form of the address encoding apparatus.

FIG. 7 is a drawing for explaining the address scrambling of a second embodiment of the invention.

FIG. 8 is a drawing showing the arrangement of the non-encoded area and encoded area in the internal address space of a second embodiment of the invention.

FIG. 9 is a flowchart of the address encoding method of a third embodiment of the invention.

FIG. 10 is a drawing for explaining the address scrambling of the third embodiment of the invention.

FIG. 11 is a drawing showing the arrangement of the non-encoded area and encoded area in the address space of the third embodiment of the invention.

FIG. 12 is a drawing for explaining the address scrambling of the third embodiment of the invention.

FIG. 13 is a schematic drawing showing the construction of the address encoding apparatus of a fourth embodiment of the invention.

FIG. 14 is a flowchart of the address encoding method of the fourth embodiment of the invention.

FIG. 15 is a drawing for explaining the address scrambling of the fourth embodiment of the invention.

FIG. 16 is a schematic drawing showing the construction of the address encoding apparatus of a fifth embodiment of the invention.

FIG. 17 is a flowchart of the address encoding method of the fifth embodiment of the invention.

### DESCRIPTION OF THE PREFERRED EMBODIMENTS

The preferred embodiments of the invention will be explained with reference to the drawings.

The address encoding apparatus of all of the embodiments is contained on the same chip as a microprocessor for example. The microprocessor inputs an internal address to the address encoding apparatus. The address encoding apparatus outputs an external address via an address bus.

First Embodiment

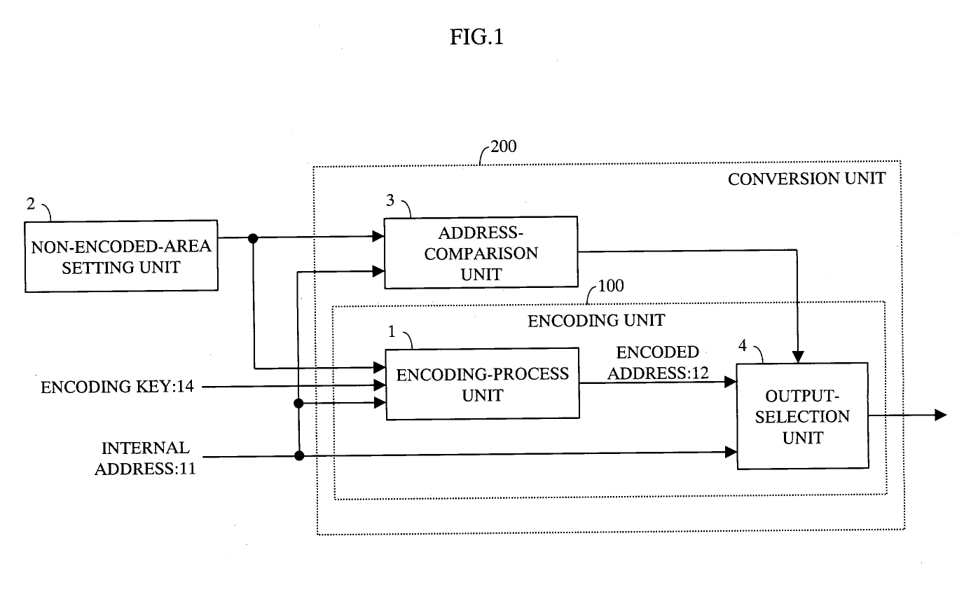

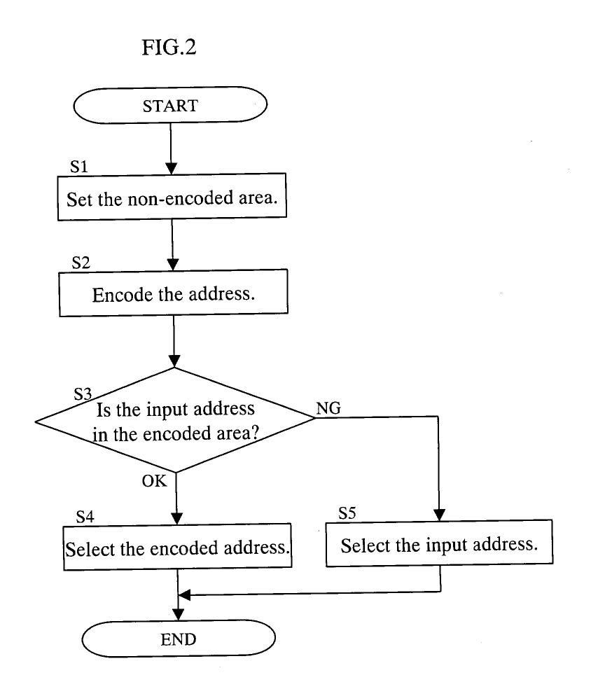

FIG. 1 is a schematic drawing showing the construction of the address encoding apparatus of a first embodiment of the invention, and FIG. 2 is a flowchart showing the address encoding method of this first embodiment.

In the address encoding apparatus, a non-encoded-area setting unit 2 is used for setting the non-encoded area, in which the internal addresses are not encoded, in the internal address space (S1).

This non-encoded-area setting unit 2 comprises a register that stores a starting address and an ending address of the non-encoded area, and those values are controlled by software.

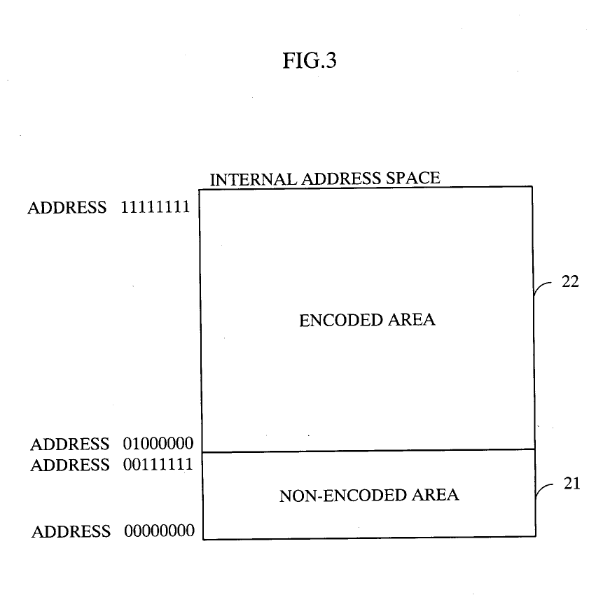

For example, in the case where a length of the internal address 11 is 8 bits, addresses from 00000000 to 11111111 are assigned in the internal address space, as shown in FIG. 3.

Here, when the register of the non-encoded-area setting unit 2 stores 00000000 as the starting address and 00111111 as the ending address, an area from address 00000000 to address 00111111 is set as the non-encoded area 21. In the internal address space, an area that is not the non-encoded area is an encoded area 22, and is the area from address 01000000 to address 11111111.

The setting of the non-encoded-area setting unit 2 is read by an encoding-process unit 1 and address-comparison unit 3 of an encoding unit 100 in a conversion unit 200. The encoding-process unit 1 encodes the input internal address 11 to create an encoded address 12 (S2).

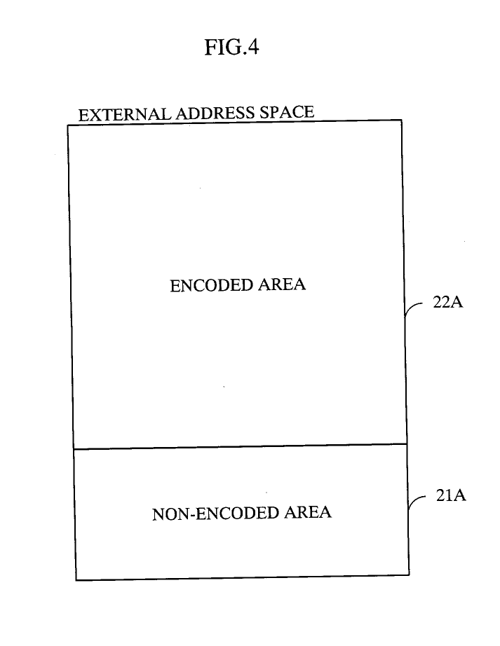

At this time, an encoding key 14 is given to the encoding-process unit 1. For example, the encoding key 14 can be prepared as a table that indicates one-on-one correspondence between an internal address that is contained in the encoded area 22 and an external address that is contained in an encoded area 22A. The encoded area 22A in the external address space corresponds to the encode area 22 in the internal address space, as shown in FIG. 4. In this case, the input internal address 11 is encoded to become the external address based on the table that is given as encoding key 14. When doing this, it is possible for a bit length of the external address to become longer than the internal address due to encoding. Here the 8-bit internal address becomes a 10-bit external address.

Based on the setting of the non-encoded-area setting unit 2, the address-comparison unit 3 determines whether the input internal address 11 is contained in the encoded area 22 or in the non-encoded area 21 (S3).

A determination is performed based on whether or not the input internal address 11 differs from values contained in the range set in the register of the non-encoded-area setting unit 2. When they differ, the address-comparison unit 3 determines that the internal address 11 is contained in the encoded area 22, and when they do not differ, the address-comparison unit 3 determines that the internal address 11 is contained in the non-encoded area 21.

The address-comparison unit 3 outputs the determination result to an output-selection unit 4. The output-selection unit 4 selects either the encoded address 12 or input internal address 11 based on the determination result from the address-comparison unit 3 and outputs it as the external address. When it is determined that the input internal address 11 is contained in the encoded area 22, the output-selection unit 4 selects the encoded address 12 (S4). In other words, an internal address that is contained in the encoded area 22 is encoded.

On the other hand, when it is determined that the input internal address 11 is contained in the non-encoded area 21, the output-selection unit 4 selects the input internal address 11 (S5). In other words, an internal address contained in the non-encoded area 21 is not encoded. When doing this, the output-selection unit 4 can add bits to the input internal address 11 so that the bit length of the output internal address is the same as that of the encoded address 12. In the case where the bit length of encoded address 12 is 10 bits, 2 bits are added. However, when adding bits, bits must be added as long as the result does not become an external address contained in the encoded area 22A.

From the above process, the external address space is divided into the encoded area 22A that contains the encoded address 12, and the non-encoded area 21A that contains the input internal address 11, as shown in FIG. 4.

The external address selected by the output-selection unit 4 is output to the memory. The external address does not directly indicate an address, so the memory must have a decoding unit that converts the external address to the internal address.

This decoding unit determines whether the external address is contained in the encoded area 22A or in the non-encoded area 21A. For example, when the table indicating conversion is given as the encoding key 14 as described above, the decoding unit performs a determination based on this table. Also, when the input external address is contained in the encoded area 22A, the decoding unit decodes the external address to become the internal address based on the table. Moreover, when the input external address is contained in the non-encoded area 21A, the decoding unit outputs the external address to become the internal address without performing decoding. In this case, if the bits are added to the external address, the decoding unit removes the added bits to become the internal address.

In this memory, the non-encoded area 21 is located in an area containing the address that the processor accesses immediately after reset. In this case, even when a third party with malice observes the address bus, it is not possible to obtain the combination of the encoded address and the address before encoding, and thus it becomes difficult to decipher the encoding key. As a result, security of the program is improved.

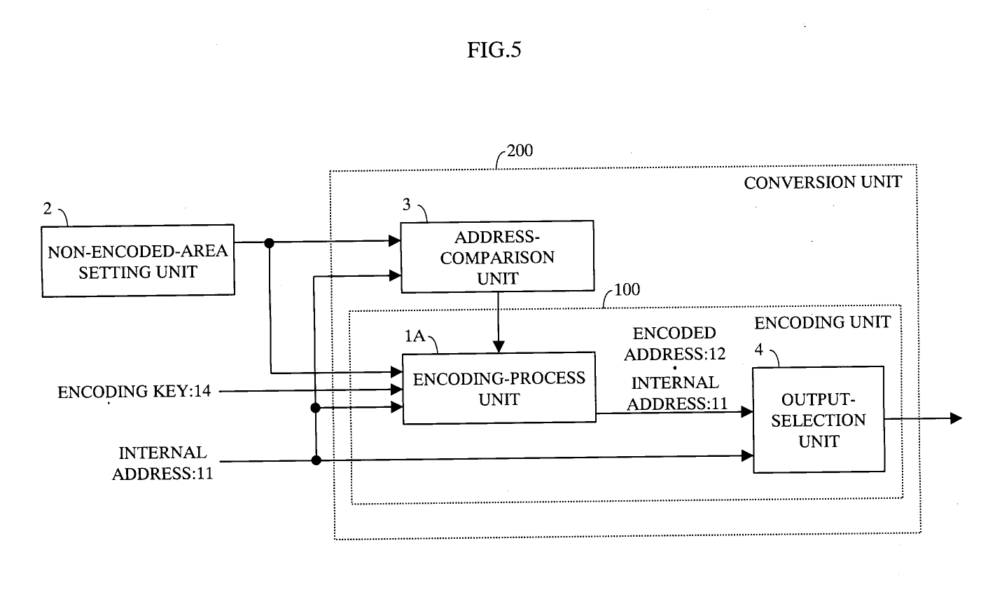

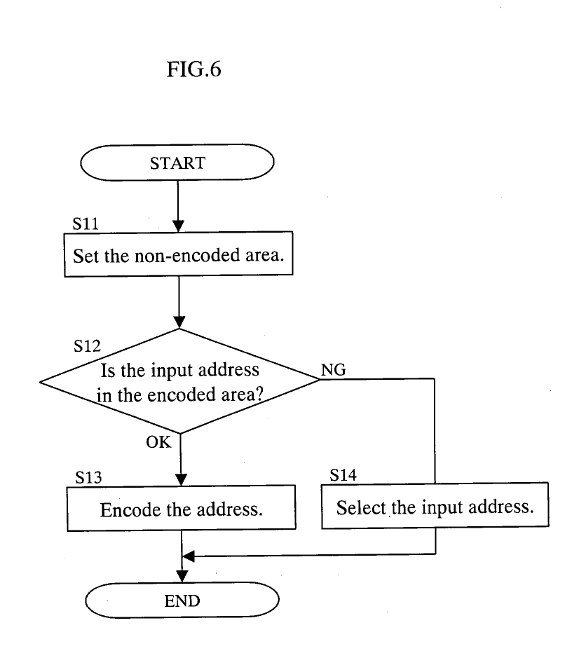

In the example shown in FIG. 1, the encoded address 12 or the input internal address 11 is selected after all of the input internal address 11 have been encoded, however the invention is not limited to this. In an example shown in FIG. 5, the address-comparison unit 3 can output the determination result to an encoding-process unit 1A. The flowchart for this case is shown in FIG. 6. After the non-encoded area is set (S11) and determination (S12) is performed as already explained, and when the address-comparison unit 3 determines that the input internal address 11 is contained in the encoded area 22, the encoding-process unit 1A creates the encoded address 12 (S13), and when the address-comparison unit 3 determines that the input internal address 11 is contained in the non-encoded area 21, the encoding-process unit 1A selects the input internal address 11 (S14). Here, when the input internal address 11 is output and bits are not added to make the bit length the same as the encoded address 12, the output of the encoding-process unit 1A can be used as the output of the encoding unit 100 without using the output-selection unit 4.

Also, in this embodiment, the non-encoded area 21 is set by the non-encoded-area setting unit 2, however, instead of this, it is possible to use an encoded-area setting unit that sets the encoded area 22. Since everywhere in the internal address space other than the encoded area 22 is the non-encoded area 21, setting the non-encoded area 21 by the non-encoded-area setting unit 2 is equivalent to setting the encoded area 22 by an encoded-area setting unit.

Second Embodiment

In this embodiment, an example of using a scrambling process for encoding the address will be explained. The construction of the encoding apparatus of this embodiment is the same as the construction of the apparatus of the first embodiment shown in FIG. 1 except that the non-encoded area is specified by upper specification bits, and that encoding is performed by the scrambling process. Also, steps of the encoding method of this embodiment are the same as steps S1 to S5 that were for explained in the first embodiment.

In the case of using the scrambling process for encoding, a register is used that stores a bit length and a value of the specification bits, and those values are controlled by software. Here, the register stores 2 as the bit length and ‘00’ as the value of the specification bits.

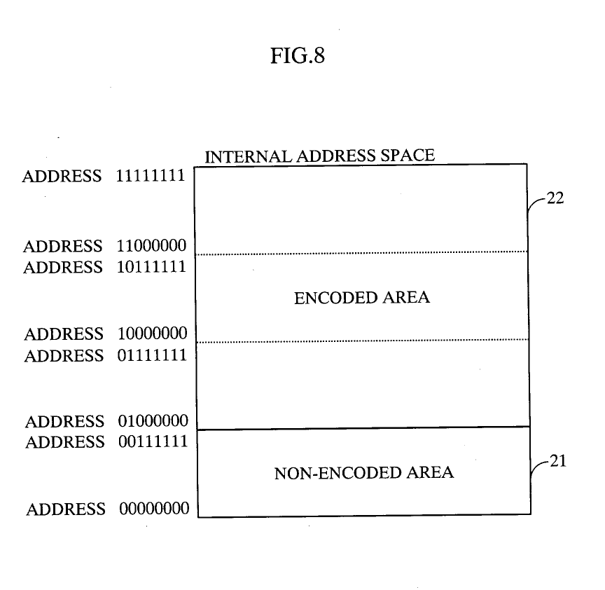

As shown in FIG. 8, when the number of bits of the internal address 11 is 8 bits, the area set as the non-encoded area 21 is specified by the upper 2 bits of the address, and the setting of the non-encoded-area setting unit 2 indicates that the area from address 00000000 to address 00111111, as upper 2 bits of the address are ‘00’, is set as the non-encoded area 21. As in the first embodiment, the encoded area 22 in the internal address space is the area from address 01000000 to address 11111111.

An encoding-process unit 1 scrambles bits of the input internal address 11 except for the upper specification bits (S2). For example, the scrambling process can be performed by calculating the exclusive OR as shown below.

The scrambling key 16 is given to the encoding-process unit 1 as the encoding key. The scrambling key 16 is expressed, for example, as a bit string having 8 bits the same as the internal address. However, in this case, the upper 2 bits of the scrambling key 16 are not used for scrambling. The encoding-process unit 2 calculates the exclusive OR between the input internal address 11 and the scrambling key 16, except for upper 2 bits. The scrambled address 15 that is scrambled by the encoding-process unit 1 is a combination of the upper 2 bits of the input internal address 11 and the results of the exclusive OR calculation.

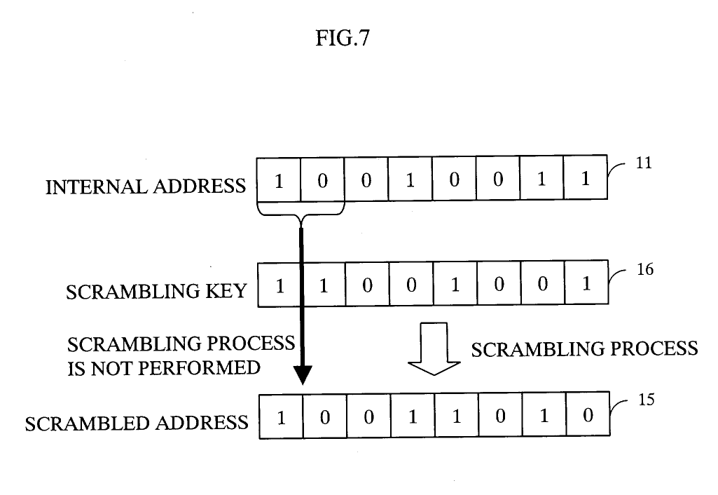

As shown in FIG. 7, when the input internal address 11 is 10010011 and the scrambling key 16 is 11001001, the exclusive OR between the input internal address 11 and the scrambling key 16, except for the upper 2 bits, becomes 011010. Since the upper 2 bits of the scrambled address 15 are ‘10’, which are the same as those of the input address 11, in this case, the address 15 that is scrambled by the encoding-process unit 1 becomes 10011010.

Based on the setting of the non-encoded-area setting unit 2, the address-comparison unit 3 determines whether the input internal address 11 is contained in the encoded area 22 or in the non-encoded area 21 (S3).

This determination is performed based on whether or not the upper 2 bits of the input internal address 11 differs from the value set in the register of the non-encoded-area setting unit 2. When they differ, the address-comparison unit 3 determines that the input internal address 11 is contained in the encoded area 22, and when they do not differ, the address-comparison unit 3 determines that the input internal address 11 is contained in the non-encoded area 21.

The address-comparison unit 3 outputs the determination results to the output-selection unit 4. As in the first embodiment, the output-selection unit 4 selects either the input internal address 11 or the scrambled address 15 that is scrambled by the encoding-process unit 1 based on the determination result from the address-comparison unit 3.

In other words, when it is determined that the input internal address 11 is contained in the encoded area 22, the output-selection unit 4 selects the scrambled address 15 (S4), and when it is determined that the input internal address 11 is contained in the non-encoded area 21, the output-selection unit 4 selects the input internal address 11 (S5).

In the case of this embodiment, the encoding-process unit 1 scrambles the bits of the internal address 11 except for the upper 2 bits, so addresses contained in the encoded area 22 are scrambled in units the same size as the non-encoded area 21. In the example shown in FIG. 8, three unit areas having the same size as the non-encoded area 21 are contained in the encoded area 22. Also, since the upper 2 bits of the encoded area 22 and the non-encoded area 21 differ regardless of scrambling, the scrambled address 15 will not be contained in the non-encoded area 21.

The address selected by the output-selection unit 4 is output to the memory via the address bus as an external address. As in the first embodiment, in this memory, the non-encoded area 21 is located in an area that contains the address, which the processor accesses immediately after reset. In this case, even though a third party with malice observes the address bus, it is not possible to obtain the combination of the scrambled address and the address before scrambling, so it becomes difficult to deciphered the scrambling key 16. As a result, security of the program is improved. Also, in the case of using scrambling for encoding, the external address directly indicates an address, so conventional products can be used with the memory and other devices. Therefore, by using scrambling for encoding, it is possible to keep down the costs of the entire system.

In this embodiment, the input internal address 11 or scrambled address 15 is selected after scrambling has been performed for all of the input internal addresses 11, however, as in the first embodiment, it is possible to use the encoding-process unit 1A, which scrambles bits of the input internal address 11 except for the specification bits, in the encoding unit 100, only in the case when the input internal address 11 is determined to be contained in the encoded area 22.

Third Embodiment

In the second embodiment, the encoding-process unit 1 scrambled the bits of the input internal address 11 except for the upper 2 bits. In this case, scrambling is performed in an area having the same size as the non-encoded area 21. However, as the unit area to be scrambled becomes small, the analytical range becomes small, so it becomes easier to decipher the scrambling key 16 by that amount.

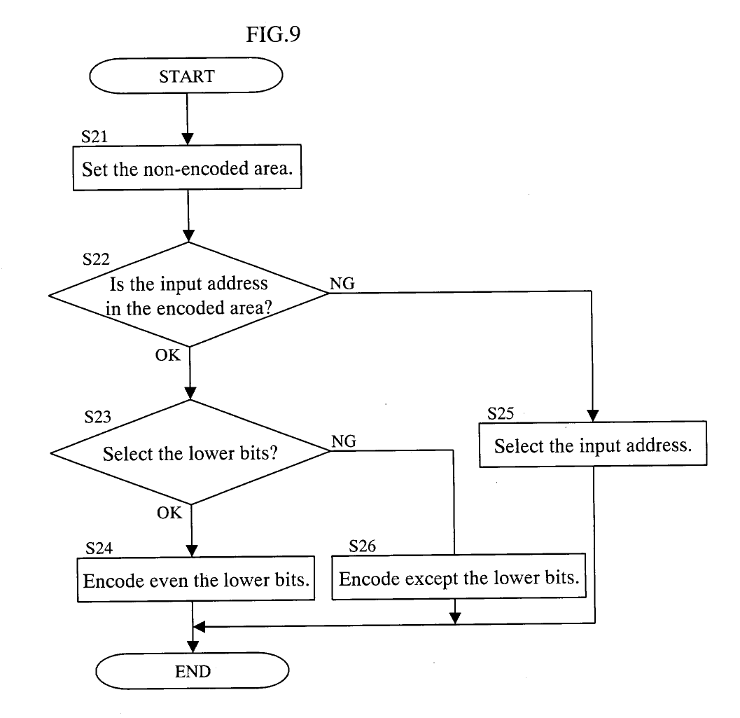

Therefore, the encoding-process unit 1 of the third embodiment selects part of lower bits of the upper specification bits based on the specification bits of the input internal address 11, and scrambles not only the bits of the input internal address 11 except for the upper specification bits, but also the selected lower bits. FIG. 9 shows a flowchart of the encoding method of this embodiment. The setting of the non-encoded area (S21), determination (S22) and selection of the input address (S25) is performed the same as steps S11, S12 and S14 as explained in the second embodiment.

When the input internal address 11 is contained in the encoded area 22, the encoding-process unit 1 selects part of lower bits of the specification bits (S23).

For example, when a bit length of the specification bits is 2 bits, and the value is ‘00’, the encoding-process unit 1 determines whether or not the upper most bit of the input internal address 11 differs from the upper most bit of the specification bits. When the upper most bit of the input internal address 11 differs from the upper most bit of the specification bits, the encoding-process unit 1 selects the lower 1 bit of the 2 bits. In this case, the encoding-process unit 1 scrambles not only the bits of the input internal address 11 except for the upper 2 bits, but also the selected 1 bit (S24). In other words, the encoding-process unit 1 calculates the exclusive OR between the input internal address 11 and the scrambling key 16, except for the upper 1 bit. The scrambled address 15 that is scrambled by the encoding-process unit 1 is a combination of the upper 1 bit of the input internal address 11 and the result of the exclusive OR calculation.

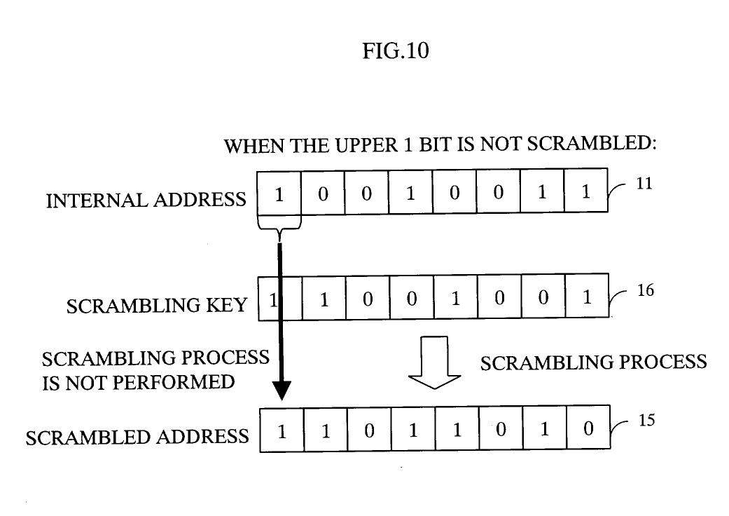

As in the example shown in FIG. 7, when the input internal address 11 is 10010011 and the scrambling key 16 is 11001001, the exclusive OR between the input internal address 11 and the scrambling key 16, except for the upper 1 bit, becomes 1011010, as shown in FIG. 10. Since the upper 1 bit of the scrambled address 15 is ‘1’, which is the same as that of the input internal address 11, so in this case, the scrambled address 15 that is scrambled by the encoding-process unit 1 becomes 11011010.

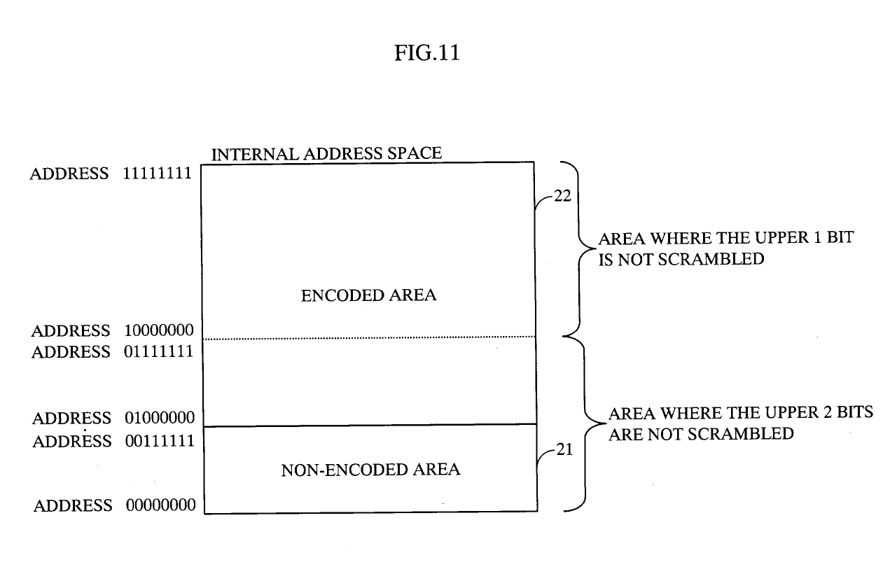

When the upper 1 bit of the input internal address 11 is ‘1’, scrambling is performed in the same way, and scrambling is performed with the area from address 10000000 to address 11111111 as the unit. In this case, as shown in FIG. 11, the size of the unit scramble area is double the size of the non-encoded area 21. In this way, the analytical range becomes larger, and it become more difficult to decipher the scrambling key 16, so security of the program is improved.

When the upper most bit of the input internal address 11 does not differ from the upper most bit of the specification bits, the encoding-process unit 1 does not select the lower 1 bit of the 2 bits (S26). In this case, the encoding-process unit 1 scrambles only the bits of the input internal address 11 except for the upper 2 bits. As in the second embodiment, the encoding-process unit 1 calculates the exclusive OR between the input internal address 11 and the scrambling key 16, except for the upper 2 bits. The scrambled address 15 that is scrambled by the encoding-process unit 1 is a combination of the upper 2 bits of the input internal address 11 and the results of the exclusive OR calculation.

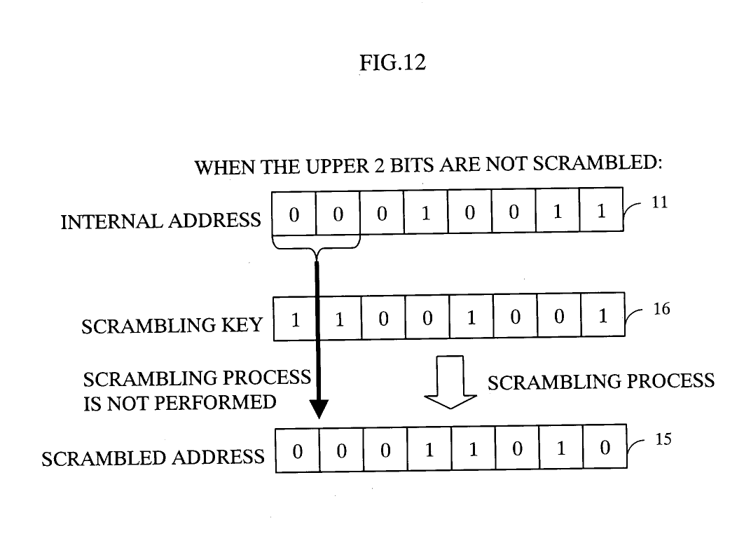

As shown in FIG. 12, when the input internal address 11 is 00010011 and the scrambling key 16 is 11001001, the exclusive OR between the input internal address 11 and the scrambling key 16, except for the upper 2 bits, is 011010. Since the upper 2 bits of the scrambled address 15 are ‘00’, which are the same as those of the input internal address 11, in this case the scrambled address 15 that is scrambled by the encoding-process unit 1 becomes 000011010.

When the upper 1 bit of the input internal address 11 is ‘0’, the same scrambling is performed, and scrambling is performed with the area from address 01000000 to address 01111111 as the unit. In this case, as shown in FIG. 11, the unit area for scrambling becomes the same size as the non-encoded area 21, and is the same as in the second embodiment. This means that the difficulty of analyzing the area from address 01000000 to address 01111111 is the same as in the second embodiment.

When the same scrambling key 16 is used for all of the unit areas for scrambling, the difficulty of analyzing each unit area depends on the difficulty of analyzing other unit areas.

Therefore, it is preferred that the encoding-process unit 1 uses a different scrambling key 16 when scrambling each unit area for scrambling.

For example, in the case that 11001001 is used as the scrambling key 16 for the area from address 01000000 to address 01111111, 00101110, which is different from 11001001, is used as the scrambling key 16 for the area from address 10000000 to address 11111111.

When the scrambling key 16 differs for each unit area for scrambling, the difficulty for analyzing each unit area is independent, and the difficulty for analyzing a large unit area is maintained.

As in the second embodiment, a different scrambling key 16 can be used for each unit area even when the size of each unit area is the same. In any case, when the scrambling key 16 for each unit area is different, even though a scrambling key 16 for one unit area is deciphered, it is possible to avoid the program saved in the remaining unit areas from being improperly obtained.

As a result, security of the program in the entire internal address space is improved.

Fourth Embodiment

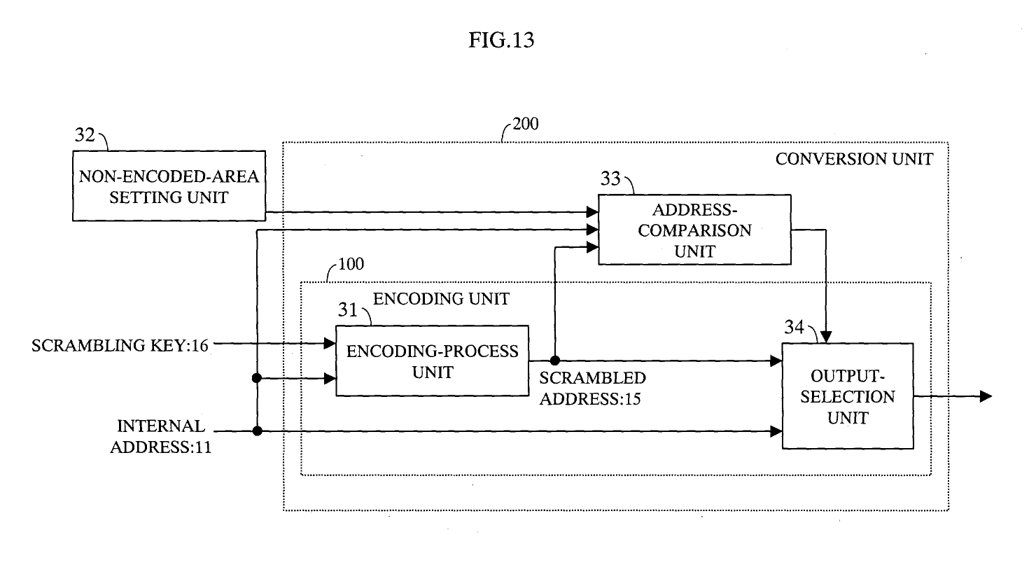

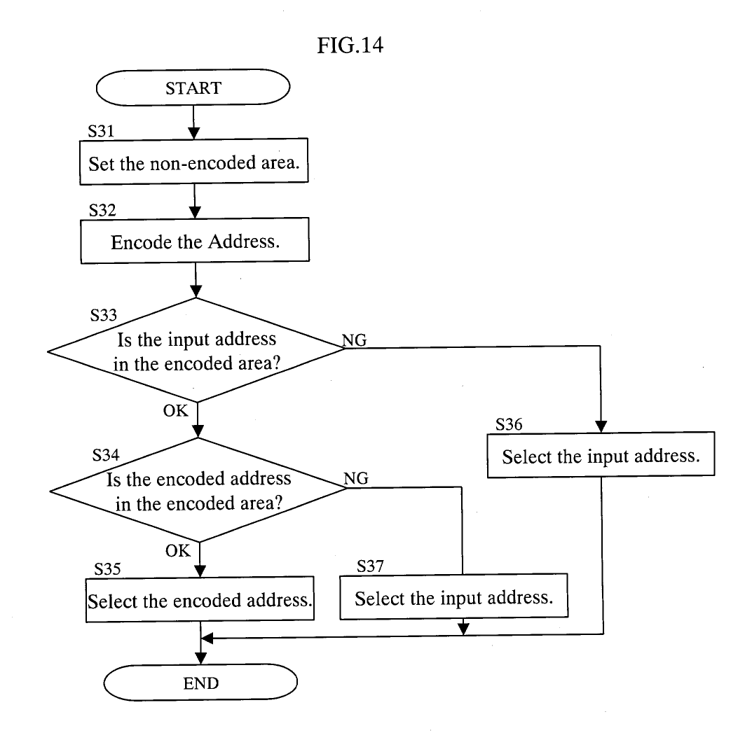

FIG. 13 is a schematic drawing showing the construction of the address encoding apparatus of a fourth embodiment. Also, FIG. 14 shows a flowchart of the address encoding method of this fourth embodiment.

In this address encoding apparatus, a non-encoded-area setting unit 32 is used for setting the non-encoded area 21, 21A, in the internal address space and external address space, in which the addresses are not scrambled (S31). Also, by setting the non-encoded area 21, 21A, the encoded area 22, 22A in the internal address space and external address space are also set.

The non-encoded-area setting unit 32 can be a register, for example, that stores a starting address and an ending address of the non-encoded area 21, 21A, and those values are controlled by software.

As in the first embodiment, the area from address 00000000 to address 11111111 is assigned for both address spaces, and 00000000 is stored in the register of the non-encoding-area setting unit 32 as the starting address, and 00111111 is contained as the ending address.

An encoding-process unit 31 scrambles the input internal address 11 (S32). A scrambling key 16 is given to the encoding-process unit 31. The scrambling key 16, for example, is a bit string that has the same bit length as the input internal address 11.

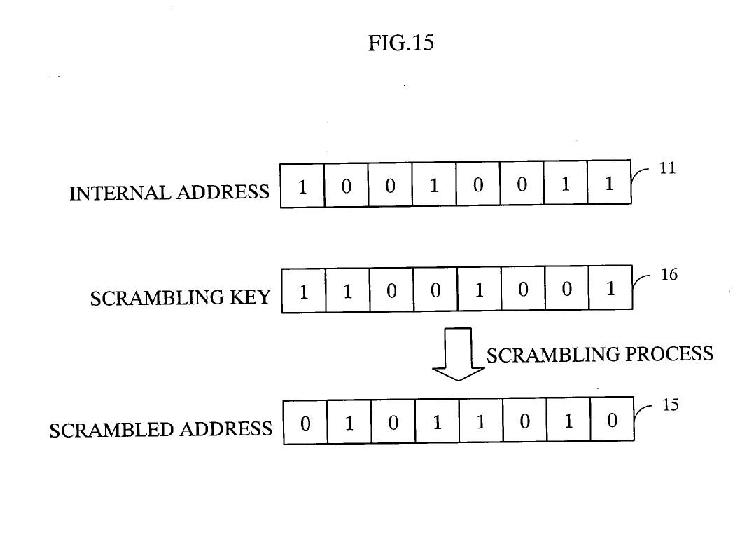

The encoding-process unit 31 calculates the exclusive OR between the input internal address 11 and the scrambling key 16. In this way, the input internal address 11 is scrambled. As shown in FIG. 15, when the input internal address 11 is 10010011 and the scrambling key 16 11001001, the scrambled address 15 becomes 01011010, which is the exclusive OR of both. Also, when the input internal address 11 is 11010011, the scrambled address 15 becomes 00011010.

An address-comparison unit 33 determines whether the input internal address 11 is contained in the encoded area 22 or in the non-encoded area 21 in the internal address space (S33), and the address-comparison unit 33 determines whether the scrambled address 15 that is scrambled by the encoding-process unit 31 is contained in the encoded area 22A or in the non-encoded area 21A in the external address space (S34).

In the case that the scrambled address 15 is 01011010, since the ending address of the non-encoded area 21A is 00111111, the address-comparison unit 33 determines the scrambled address 15 is contained in the encoded area 22A. Also, in the case that the scrambled address 15 is 00011010, the address-comparison unit 33 determines the scrambled address 15 is contained in the non-encoded area 21A.

The determination result of the address-comparison unit 33 is output to an output-selection unit 34. Of the input internal address 11 and the scrambled address 15, the output-selection unit 34 selects the scrambled address 15 only when the input internal address 11 is contained in the encoded area 22 and the scrambled address 15 is contained in the encoded area 22A (S35). On the other hand, in all cases except for above case, the output-selection unit 34 selects the input internal address 11 (S36, S37).

For example, when the input address 11 is 10010011 and the scrambled address 15 is 01011010, of the input internal address 11 and the scrambled address 15, the scrambled address 15 is selected according to the determination result of the address-comparison unit 33.

However, when the input internal address 11 is 11010011 and the scrambled address 15 is 00011010, the input internal address 11 is selected. The address that becomes 11010011 when the input internal address 11 is scrambled by linear scrambling such as calculating the exclusive OR with the scrambling key 16, is only 00011010, and since the internal address 11 is in the non-encoded area 21, the input internal address 11 is selected and the scrambled address 15 is not selected. In this way, an external address that is selected when an internal address is contained in the non-encoded area 21, and the external address that is selected when the internal address is contained in the encoded area 22 are not the same.

The external address that is selected by the output-selection unit 34 in this way is output to the memory via the address bus. As in the first embodiment, in this memory, the non-encoded area 21 is located, for example, in an area containing the address that the processor accesses immediately after reset. In this case, even though a third party with malice observes the address bus, it is not possible to obtain the combination of the scrambled address and address before scrambling, and thus it becomes difficult to decipher the scrambling key. As a result, security of the program is improved. Also, since scrambling is performed with an area in the internal address space other than the non-encoded area as the scrambling unit, the analysis range becomes large. As a result, it becomes extremely difficult to decipher the scrambling key.

In this embodiment, encoding is performed using the scrambling process, however the embodiment is not limited to this, and an encoding method other than the scrambling process can be used.

In the case of the encoding method other than the scrambling process, it is possible to make it even more difficult to decipher the encoding key.

Fifth Embodiment

In the case where the memory to which the external address is output from the address encoding apparatus via the address bus is a RAM, there is a possibility that the scrambled address will be scattered over a plurality of pages when the RAM page size and a unit area for scrambling are different. In that case, there will be a drop in a performance for accessing the RAM. Therefore, it is preferred that the unit area for scrambling by the encoding-process unit is the same as the RAM page size.

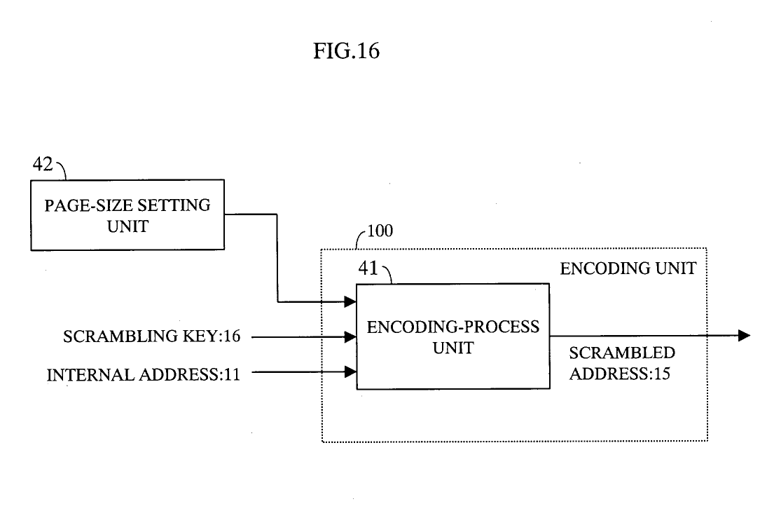

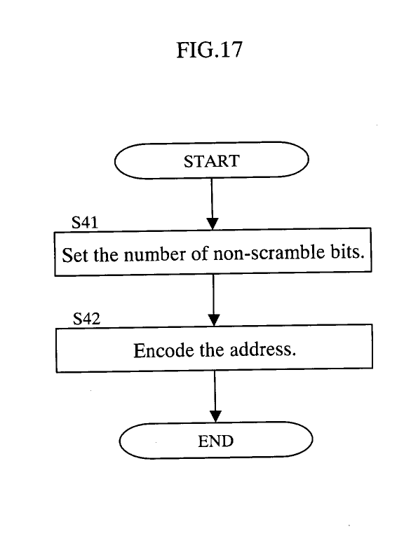

As shown in FIG. 16, in order to do this, the address encoding apparatus of this fifth embodiment has a page-size setting unit 42. FIG. 17 shows a flowchart for this process.

The page-size setting unit 42 is a register used for setting the RAM page size. This register stores a value of the RAM size, and that value is controlled by software.

According to the setting of the page-size setting unit 42, the encoding-process unit 41 sets the number of non-scramble bits that are not scrambled (S41). For example, when a length of the input internal address 11 is 16 bits and the page-size is 4K bytes, the encoding-process unit 41 subtracts 15 bits from 16 bits and sets 1 bit as the number of non-scramble bits.

The encoding-process unit 41 scrambles bits of the internal address 11 except upper bits equal to the number of non-scramble bits (S42). In the case where the number of non-scramble bits is 1 bit, the encoding-process unit 41 scrambles the bits of the input internal address 11 except the upper 1 bit. In this case, 15 bits are scrambled and the upper 1 bit is not scrambled.

By doing this, the scrambled address 15 is scrambled in page-size units. As a result, it is possible to keep the performance of accessing the RAM from dropping due to scrambling.

In the address encoding apparatus of this fifth embodiment as well, the encoding-process unit 41 can be such that a different scrambling key 16 is used for each unit area for scrambling.

Also, the address space, addresses, scrambling keys 16, the arrangement of the non-encoded areas 21, 21A, and the arrangement of the encoded areas 22, 22A in the address space described for each of the embodiments above are examples and they do not limit the technical range of this invention.

As explained above, in this invention, part of the area in the internal address space is set as the non-encoded area in which addresses are not encoded, so even though the address bus may be observed immediately after reset, it is not possible to obtain the combination of the encoded address and the address before encoding. Doing this makes it difficult to decipher the encoding key used in encoding, and improves security of the program.

Particularly, in the case of using scrambling for encoding, it is possible to use conventional products as devices such as the memory that outputs addresses via the address bus, and thus is economical.

What is claimed is:

1. An address encoding apparatus that converts an internal address to an external address and outputs the external address, and that comprises:
a non-encoded-area setting unit that sets a non-encoded area, in an internal address space, in which internal addresses are not encoded; and
a conversion unit that outputs an external address which is an internal address that have been encoded based on said internal address and said non-encoded area.

2. The address encoding apparatus of claim 1 wherein said conversion unit comprises:
an address-comparison unit that determines whether an input internal address is contained in an encoded area that is an area in said internal address space other than said non-encoded area, or in said non-encoded area; and
an encoding unit that encodes said input internal address to an external address in an area, in an external address space, that corresponds to said encoded area only when it is determined that said input internal address is contained in said encoded area.

3. The address encoding apparatus of claim 1 wherein said conversion unit comprises:
an encoding-process unit that encodes an input internal address;
an address-comparison unit that determines whether said input internal address is contained in an encoded area that is an area in said internal address space other than said non-encoded area, or in said non-encoded area, and determines whether said encoded internal address is contained in a corresponding area, in an external address space, that corresponds to said non-encoded area, or in a non-corresponding area that is an area in said external address space other than said corresponding area; and
an output-selection unit that selects said encoded internal address from among said input internal address and encoded internal address only when it is determined that said input internal address is contained in said encoded area and that said encoded internal address is contained in said non-corresponding area.

4. An address encoding apparatus that scrambles an address and comprises:
a non-encoded-area setting unit that sets into an area specified by upper specification bits of an address in an address space a non-encoded area in which addresses are not scrambled;
an address-comparison unit that determines whether an input address is contained in an encoded area that is not an area in said address space other than said non-encoded area, or in said non-encoded area; and
an encoding unit that scrambles bits of an input address except said specification bits only when it is determined that said input address is contained in said encoded area.

5. The address encoding apparatus of claim 4 wherein said encoding unit comprises:
an encoding-process unit that scrambles bits of an input address except said specification bits; and
an output-selection unit that selects said scrambled address from among said input address and scrambled address when it is determined that said input address is contained in said encoded area, and selects said input address when it is determined that said input address is contained in said non-encoded area.

6. The address encoding apparatus of claim 4 wherein said encoding unit selects part of lower bits of said specification bits based on said specification bits of an input address, and scrambles not only the bits of said input address except for said specification bits, but also said selected bits.

7. An address encoding apparatus that scrambles an address and comprises:
an encoding-process unit that scrambles an input address;
a non-encoded-area setting unit that sets a non-encoded area, in an address space, in which addresses are not scrambled;
an address-comparison unit that determines whether said input address is contained in an encoded area that is an area in said address space other than said non-encoded area, or in said non-encoded area, and determines whether said scrambled address is contained in said encoded area or in said non-encoded area; and
an output-selection unit that selects said scrambled address from among said input address and scrambled address only when it is determined that said input address is contained in said encoded area and that said scrambled address is contained in said encoded area.

8. An address encoding apparatus comprising:
a page-size setting unit for setting a RAM page size; and
an encoding unit that sets a number of non-scramble bits that are not scrambled, based on the setting of said page-size setting unit, and scrambles bits of said input address except for upper bits equal to the number of non-scramble bits.

9. The address encoding apparatus of the claims 4 wherein said encoding unit uses a different scrambling key, which is used in scrambling, for each unit area for scrambling.

10. The address encoding apparatus of the claims 5 wherein said encoding unit uses a different scrambling key, which is used in scrambling, for each unit area for scrambling.

11. The address encoding apparatus of the claims 6 wherein said encoding unit uses a different scrambling key, which is used in scrambling, for each unit area for scrambling.

12. The address encoding apparatus of the claims 8 wherein said encoding unit uses a different scrambling key, which is used in scrambling, for each unit area for scrambling.

13. An address encoding method that converts an internal address to an external address and outputs the external address and that comprises:
a step of determining whether an input internal address is contained in a non-encoded area that is set in an internal address space and in which internal addresses are not encoded, or in an encoded area that is an area in said internal address other than said non-encoded area; and
a step of encoding said input internal address to an external address in an area, in an external address space, that corresponds to said encoded area only when it is determined that said input internal address is contained in said encoded area.

14. An address encoding method that converts an internal address to an external address and outputs the external address and that comprises:
a step of encoding an input internal address;
a step of determining whether said input internal address is contained in a non-encoded area that is set in an internal address space and in which internal addresses are not encoded, or in an encoded area that is an area in said internal address space other than said non-encoded area, and determines whether said encoded internal address is contained in a corresponding area, in an external address space, that corresponds to said non-encoded area, or in a non-corresponding area that is an area in said external address space other than said corresponding area; and
a step of selecting said encoded internal address from among said input internal address and encoded internal address only when it is determined that said input internal address is contained in said encoded area and that said encoded internal address is contained in said non-corresponding area.

15. An address encoding method of scrambling an address and comprising:
an address-comparison step of determining whether an input address is contained in a non-encoded area that is set into an area specified by upper specification bits of an address and in which addresses are not scrambled, or in an encoded area that is an area in said address space other than said non-encoded area; and
an encoding step of scrambling bits of an input address except said specification bits only when it is determined that said input address is contained in said encoded area.

16. The address encoding method of claim 15 wherein said encoding step comprises:
an encoding-process step of scrambling said bits of an input address except said specification bits; and
a selection step of selecting a scrambled address from among said input address and scrambled address when it is determined that said input address is contained in said encoded area, and selecting said input address when it is determined that said input address is contained in said non-encoded area.

17. The address-encoding method of claim 15 wherein said encoding step is a step of selecting part of lower bits of said specification bits based on said specification bits of an input address, and scrambling not only bits of said input address except for said specification bits, but also said selected bits.

18. An address encoding method of scrambling an address comprising:
a step of scrambling an input address;
a step of determining whether said input address is contained in a non-encoded area that is set in an address space and in which addresses are not scrambled, or in an encode area that is an area in said address space other than said non-encoded area, and determining whether said scrambled address is contained in said encoded area or in said non-encoded area; and
a step of selecting said scrambled address from among said input address and scrambled address only when it is determined that said input address is contained in said encoded area and that said scrambled address is contained in said encoded area.

19. An address encoding method comprising:
a determining step of determining a number of non-scramble bits that are not scrambled, based on a RAM page size; and
an encoding step of scrambling bits of an input address except for upper bits equal to the number of non-scramble bits.

20. The address encoding method of the claims 15 wherein said encoding step uses a different scrambling key, which is used in scrambling, for each unit area for scrambling.

21. The address encoding method of the claims 16 wherein said encoding step uses a different scrambling key, which is used in scrambling, for each unit area for scrambling.

22. The address encoding method of the claims 17 wherein said encoding step uses a different scrambling key, which is used in scrambling, for each unit area for scrambling.

23. The address encoding method of the claims 19 wherein said encoding step uses a different scrambling key, which is used in scrambling, for each unit area for scrambling.

24. A program which makes a computer execute:
a step of determining whether an input internal address is contained in a non-encoded area that is set in an internal address space and in which internal addresses are not encoded, or in an encoded area that is an area in said internal address space other than said non-encoded area; and
a step of encoding said input internal address to an external address in an area, in an external address space, that corresponds to said encoded area only when it is determined that the input internal address is contained in said encoded area.

25. A program which makes a computer execute:
a step of encoding an input internal address;
a step of determining whether said input internal address is contained in a non-encoded area that is set in an internal address space and in which internal addresses are not encoded, or in an encoded area that is an area in said internal address space other than said non-encoded area, and determines whether said encoded internal address is contained in an area, in the external address space, that corresponds to said non-encoded area, or in a non-corresponding area, that is an area in said external address space other than said corresponding area; and
a step of selecting said encoded internal address from among said input internal address and encoded internal address only when it is determined that said input internal address is contained in said encoded area and that said encoded internal address is contained in said non-corresponding area.

26. A program which makes a computer execute:
a step of determining whether an input address is contained in a non-encoded area that is set into an area specified by upper specification bits of an address and in which addresses are not scrambled, or in an encoded area that is an area in said address space other than said non-encoded area; and
a step of scrambling bits of said input address except said specification bits only when it is determined that said input address is contained in said encoded area.

27. A program which makes a computer execute:
a step of scrambling an input address;
a step of determining whether said input address is contained in a non-encoded area that is set in an address space and in which addresses are not scrambled, or in an encode area that is an area in said address space other than said non-encoded area, and determining whether said scrambled address is contained in said encoded area or in said non-encoded area; and
a step of selecting said scrambled address from among said input address and scrambled address only when it is determined that said input address is contained in said encoded area and that said scrambled address is contained in said encoded area.

28. A program which makes a computer execute:
a step of determining a number of non-scramble bits that are not scrambled, based on a RAM page size; and
a step of scrambling bits of an input address except for upper bits equal to the number of non-scramble bits.
